(19) United States
(12) Patent Application Publication
(10) Pub. No.: US 2007/0177356 A1
(43) Pub. Date: Aug. 2, 2007

(54) THREE-DIMENSIONAL COLD PLATE AND METHOD OF MANUFACTURING SAME

(76) Inventor: Jeffrey Panek, North Kingstown, RI (US)

Correspondence Address: BARLOW, JOSEPHS & HOLMES, LTD., 101 DYER STREET, 5TH FLOOR, PROVIDENCE, RI, 02903, US

(21) Appl. No.: 11/626,894

(22) Filed: Jan. 25, 2007

Related U.S. Application Data
(60) Provisional application No. 60/743,207, filed on Feb. 1, 2006.

(51) Int. Cl. H05K 7/20

(52) U.S. Cl. 361/712; 361/720

(57) ABSTRACT

A three-dimensional cold plate assembly and method of manufacturing the same is disclosed. The cold plate assembly includes a metallic substrate having a top side and a bottom side and a three-dimensional molded contoured plastic body having a top side and a bottom side. The bottom side of the metallic substrate is bonded to the top side of the plastic body. The bottom side of the plastic body is contoured to substantially complementarily mate with a profile of heat generating components in an electronic device. The method of manufacturing the cold plate includes the steps of pretreating and cleaning the metallic substrate, etching the metallic substrate and overmolding the plastic body onto the bottom side of the metallic substrate to provide a bottom contoured side of the plastic body that substantially complementarily mates with the profile of heat generating components in an electronic device.

### CROSS-REFERENCE TO RELATED APPLICATION

This application claims priority to earlier filed U.S. Provisional Application Ser. No. 60/743,207, filed Feb. 1, 2006, the contents of which are incorporated herein by reference.

### BACKGROUND OF THE INVENTION

1. Field of the Invention

The present invention relates generally to transferring heat away from heat generating components. The present invention relates to devices and methods of manufacturing such devices for dissipating heat generated by such devices. More specifically, the present invention relates to devices for transferring heat away from heat generating electronic components, such as those found in power supplies and converters.

2. Background of the Related Art

In the electronics and computer industries, it has been well known to employ various types of electronic device packages and integrated circuit chips and components, such as those for CPUs, RAM and power purposes. These electronic devices and components generate a great deal of heat during operation which must be removed to prevent adverse effects on operation of the system into which the device is installed. For example, a CPU packages, containing millions of transistors, and power components are highly susceptible to overheating which could destroy the device itself or other components proximal to the package.

If such heat is not properly dissipated from these devices, the device or component will eventually fail or cease to operate properly. For example, a number of electronic devices may be installed proximal to one another in a cluster on a particular region on a circuit board. If each of these devices require cooling to avoid failure, some type of heat dissipation is necessary.

In the prior art, it has been common to provide “bulk” cooling to a group of devices that require heat dissipation. In these devices, a single heat sink is placed over all of the devices that required cooling. For example, a block heat sink with a base with a flat bottom and upstanding pins, is dimensioned large enough to rest on the top heat generating surfaces of each of the heat generating devices. In this prior art assembly, the base of the heat sink member is affixed to the top surfaces of the devices to be cooled by a thermally conductive epoxy, thermally conductive double-side tape, and the like. As a result, a single heat sink member may simultaneously provide heat dissipating for a number of devices.

For example, in the environment of a power supplies and converters, it is common to include a stamped sheet of metal with a dielectric surface with a compliant material on one side to interface with the lid of the device. See prior art FIG. 1, attached. Prior art cold plate assemblies 8 include a three-dimensional metal body 10 is positioned on the other side of the sheet of metal 12 to interface with the heat generating components 14 of the device. The metal body 10 is configured to conform to the contours of the heat generating components 14, which are commonly positioned on a circuit board 16, or the like. A further dielectric coating 18 is typically also provided between the three-dimensional metal body 10 and the heat generating components 14 to absorb the gap therebetween.

The foregoing attempts in the prior art suffer from the disadvantages employing a large heavy cast or machined metal body. The cold plate construction of the prior art has poor creep resistance where temperature changes greatly affects the ability of the metal body 10 and interface materials 20 between it and the lid 22 and heat generating components 14 to form good thermal communication. Also, it is very costly to machine or cast a large three-dimensional metal body 10 with precision.

In view of the foregoing, there is a demand for a cold plate assembly that is capable of dissipating heat from a group of heat generating components simultaneously. There is a demand for a cold plate assembly that is particularly well-suited for cooling components in power supply and power converted environments. In addition, there is a demand for a complete cold plate assembly that is less expensive to manufacture than prior art assemblies without sacrificing thermal conductivity performance.

### SUMMARY OF THE INVENTION

The present invention preserves the advantages of prior art cold plate assemblies for heat generating components, such as power components and microprocessors. In addition, it provides new advantages not found in currently available assemblies and overcomes many disadvantages of such currently available assemblies.

The invention is generally directed to the novel and unique cold plate assembly with particular application in cooling heat generating electronic components, such as power components installed on a circuit board. The cold plate assembly of the present invention enables the simple, easy and inexpensive assembly, use and maintenance of a cold plate assembly while realizing superior thermal conductivity and heat dissipation. The cold plate of the present invention has particular application in simultaneously providing heat dissipation for a number of heat generating electronic components that may be of different sizes, shapes, configurations and heights or thicknesses.

The present invention uniquely employs a three-dimensional, preferably molded, plastic body that resides between a metallic substrate and the heat generating electronic components to be cooled. The electronic components are shown in FIG. 2 and described herein as being populated on a circuit board, which is by way example only. A circuit board may not be used at all.

### BRIEF DESCRIPTION OF THE DRAWINGS

These and other features, aspects, and advantages of the present invention will become better understood with reference to the following description, appended claims, and accompanying drawings where:

FIG. 1 shows a prior art cold plate assembly; and

FIG. 2 shows the cold plate assembly of the present invention.

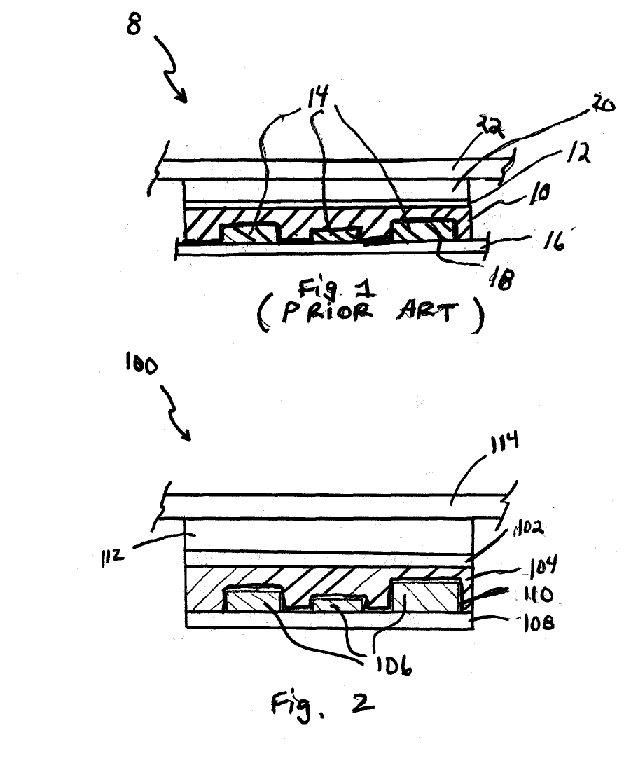

### DETAILED DESCRIPTION OF THE PREFERRED EMBODIMENT

Referring to FIG. 2, the cold plate assembly of the present invention is shown generally at 100. The cold plate assembly 100 of the present invention includes the following components: a metallic substrate 102, a plastic body 104 having a contoured surface attached to the metallic substrate, and a thermally conductive layer is formed on the plastic body and metallic substrate.

A metallic substrate 102 of preferably aluminum or copper is used. Although aluminum and copper are preferred, any metal or metal alloy can be used. Preferably the metallic substrate 102 should have high thermal conductivity and be lightweight. As will be described in greater detail below, the metallic substrate 102 of appropriate size is selected and prepared to a good bond with a polymer. Typically, the metallic substrate 102 is a flat plate stamped to size, however, it could be formed by another process, e.g. a stamped plate with 3D features, a coined plate, or a cast part for instance. Whichever method is used, it is desirable that the metallic substrate 102 can bond well with a plastic.

A plastic body 104 is attached to the metallic substrate 102 on one side such as by adhesive, insert molding, and the like. The opposite side of the plastic body 104 is contoured to mate closely with the profile of the heat generating components 106. Preferably, the plastic body 104 is molded from a thermally conductive dielectric (or electrically conducting for certain applications requiring shielding materials or shielding gaskets) polymer in contact with the prepared metallic substrate 102 while providing a three-dimensional shape on the opposite surface that closely follows the contours of the heat generating components 106 and other components of an electrical device 108. Suitable polymers for the plastic body 104 include polycarbonates, polyethylene, polypropylene, acrylics, vinyls, fluorocarbons, polyamides, polyesters, polyphenylene sulfide (“PPS”), and liquid crystal polymers. Preferably PPS is used, however.

The polymer can be optionally loaded with a filler to enhance its thermal conductivity. Suitable fillers include ceramics, metal oxides, and carbon materials, and more specifically silicon nitride, boron nitride, alumina, magnesium oxide, and carbon graphite.

A preferably dielectric interface material 110 is provided between the contoured plastic body 104 and the heat generating components 106 to provide direct contact between the heat generating components and the thermally conductive molded plastic. For instance a thermally conductive tape, gap filling or other interface materials can be used. A thermal interface layer 112 is also formed between the metallic substrate and a lid 114 of the electrical device 108.

Instead of using a thermal interface material for components 110, 112, the plastic body 104 can be overmolded over the metallic substrate 102 whereby a portion of the plastic between the metallic substrate 102 and the lid 114 and the heat generating components 106 serves as an interface material 110, 112 therebetween, respectively. In this embodiment, a thermally conductive and mechanically compliant plastic material is overmolded with the metallic substrate 102. The compliant material also may eliminate or reduce the need or thickness of the tape or interface material 110, 112.

It is also possible to overmold a compliant plastic over the contoured plastic body 104 to serve as an interface material 110, 112 between either or both the plastic body 104 and the heat generating components 106 and the metallic substrate 102 and the lid 114 of the device. In this embodiment of the present invention, a thermally conductive and mechanically compliant plastic material is overmolded onto the harder thermally conductive plastic body 104. This layer can substitute for a thermally conductive tape or interface material and can serve as part of the gasketing or shielding requirements.

Other supplemental heat transfer devices, such as heat pipes and flow channels, can be embedded in the plastic body 104 and/or metallic substrate 102 to enhance thermal conductivity of the cold plate assembly 100.

The method manufacturing the cold plate assembly 100 of the present invention provides a unique process that is not found in the prior art. More specifically, the present invention provides a unique process for bonding plastic to a metallic substrate 102. Good heat transfer is dependent on providing intimate thermal/mechanical contact between dissimilar materials. The mechanical integrity and, therefore, heat transfer reliability of this bond during the lifetime use is important. Typically is difficult to bond polymers to metallic substrates. In the bonding of polymers to metallic substrates it is generally preferred to start with low viscosity polymers or solutions to ensure good wet out of the metallic substrate. Molded thermoplastics are typically even more difficult to bond to metallic substrates because their viscosity (even in the melt) is quite high and they typically do not have reactive chemistry that might help wet out or bond to a metallic surface. Additionally, the high temperature thermoplastics that are advantageous in these applications for their high temperature stability and flame retarding characteristic tend to have even higher viscosity and less chemical reactivity than other thermoplastics. These characteristics further reduce the ability to form strong adhesive bonds to metals. Additionally, the thermally conductive high temperature plastics, that are required to allow heat transfer, typically have a lower coefficient of thermal expansion than the metal substrate. The mismatch in coefficient of thermal expansion creates stresses between that metallic substrate and the overmolded polymer as the part is exposed to temperature excursions during use. Good adhesive strength is required to overcome the thermal and mechanical loads placed on component during use.

The method to form the article of the present invention preferably employs a low viscosity high temperature polymer. Thus, good wet out and strong adhesive bonds between metal and plastic can be formed. To ensure good adhesive strength, the metallic substrate 102 is pretreated, cleaned and etched and then anodized to create a porous surface. The plastic body 104 is then overmolded over the anodized metallic substrate 102 within a time period before the porous surface seals or corrodes due to environmental exposure.

The table below in paragraph [30] compares the properties of four comparative examples with two examples of the present invention. Comparative Examples 1 and 2 were formed from a flat plate with an interface material. However, the plate and interface material were not shaped to conform to the heat generating components of an electrical device. The primary difference between Comparative Example 1 and Comparative Example 2 is the choice of whether to use an aluminum plate or a copper plate.

Comparative Examples 3 and 4 are similar to Comparative Examples 1 and 2, but differ in the metallic plate has a three-dimensional surface conformed to fit the heat generating components of an electrical device. Comparative Examples 3 and 4 further include a dielectric coating. Comparative Examples 3 and 4 also differ in whether the metallic plate was formed from aluminum or copper.

Examples 1 and 2 of the present invention were prepared using an aluminum or copper plate as a metallic substrate, respectively, and overmolding a three-dimensional plastic body including PPS loaded with boron nitride over the metallic substrate.

TABLE

| | Comparative Examples | Comparative Examples | |
|---|---|---|---|
| | 1 and 2 | 3 and 4 | Examples 1 and 2 |
| | flat plate + interface | 3D plate + dielectric | plate + 3D plastic + interface |
| | material | coating + interface | material |
| Property | (Prior Art) | material (Prior Art) | (Present Invention) |
| Conductivity of metal | Aluminum max 200 W/mK | Aluminum 80–200 W/mK | Aluminum max 200 W/mK |
| plate | Copper max 400 W/mK | (machining/casting alloy | Copper max 400 W/mK |
| | | preferred) | |
| | | Copper 250–400 W/mK | |
| | | (machining alloy | |
| | | preferred) | |
| Conformal design of | No | Yes | Yes |
| hard dielectric layer to | | | |
| device architecture | | | |
| Max. tolerance hard lid | <0.250 inch | <0.010 inch | <0.004 inch |
| to component | | | |
| Thermal conductivity of | 30 W/mK (alumina) | 0.3–0.4 W/mK | 10 W/mK |
| hard dielectric layer on | | | |
| lid | | | |
| Typical thickness of | <0.001 inch | 0.003 to 0.010 inch | 0.010 to 0.250 inch |
| hard dielectric layer | | | |
| Continuous use temp of | >300 deg C. | 130 deg C. | 180 deg C. |
| hard dielectric layer on | | | |
| lid | | | |
| Dielectric strength of | Concern over porosity | 1200 V/mil | 900 V/mil |
| hard dielectric layer on | | | |
| lid | | | |
| Volume resistivity of | 10E12 ohm-cm(concern | 4E06 ohm-cm | 1E14 ohm-cm |
| hard dielectric layer on | over porosity) | | |
| lid | | | |
| Dielectric Constant of | 9.0 | 6.0 | 3.2 |
| hard dielectric layer on | | | |
| lid | | | |
| Flammability of hard | V0 | V0 | V0 |
| dielectric layer on lid | | | |
| Adhesion of hard | NA | Good | Good |
| dielectric layer to lid | | | |
| Specific gravity of hard | 3.5 | 1.6 | 1.7 |
| dielectric layer | | | |
| Typical heat transfer | Poor vs. no enclosure/lid | Equivalent or poorer vs. | Improvement vs. no |
| performance in | | no enclosure/lid | enclosure/lid |
| application | | | |

Therefore, it can be seen that the present invention provides a unique solution to the problem of providing a cold plate assembly that shows improved heat dissipation characteristics and is less expensive to manufacture than the machined metal parts of the prior art.

It would be appreciated by those skilled in the art that various changes and modifications can be made to the illustrated embodiments without departing from the spirit of the present invention. All such modifications and changes are intended to be within the scope of the present invention except as limited by the scope of the appended claims.

What is claimed is:

1. A three-dimensional cold plate assembly for an electronic device with heat generating components, comprising:
a metallic substrate having a top side and a bottom side;
a three-dimensional molded contoured plastic body having a top side and a bottom side; the bottom side of the metallic substrate being bonded to the top side of the plastic body; the bottom side of the plastic body being contoured to substantially complementarily mate with a profile of heat generating components in an electronic device.

2. The assembly of claim 1, further comprising:
a first thermal interface layer formed on the bottom side of the plastic body.

3. The assembly of claim 2, wherein said first thermal interface layer is a thermally conductive tape.

4. The assembly of claim 1, further comprising:
a second thermal interface layer formed on the top of the metallic substrate.

5. The assembly of claim 1, wherein the metallic substrate is selected from the group consisting essentially of metals and metal alloys.

6. The assembly of claim 1, wherein the plastic body is formed from a thermoplastic polymer.

7. The assembly of claim 6, wherein said thermoplastic polymer is a dielectric material.

8. The assembly of claim 1, wherein the plastic body is formed from a thermoplastic polymer selected from the group consisting essentially of polycarbonates, polyethylene, polypropylene, acrylics, vinyls, fluorocarbons, polyamides, polyesters, polyphenylene sulfide, and liquid crystal polymers.

9. The assembly of claim 1, wherein said plastic body further comprises a thermally conductive filler.

10. The assembly of claim 9, wherein said thermally conductive filler is selected from the group consisting essentially of ceramics, metal oxides, and carbon materials.

11. The assembly of claim 2, wherein said first thermal interface layer further comprises a thermally conductive filler selected from the group consisting of silicon nitride, boron nitride, alumina, magnesium oxide, and carbon graphite.

12. The assembly of claim 4, wherein said second thermal interface layer further comprises a thermally conductive filler selected from the group consisting of silicon nitride, boron nitride, alumina, magnesium oxide, and carbon graphite.

13. The assembly of claim 9, wherein the thermally conductive filler is selected from the group consisting of silicon nitride, boron nitride, alumina, magnesium oxide, and carbon graphite.

14. The assembly of claim 1, further comprising at least one heat transfer device in thermal communication with the metallic substrate.

15. The assembly of claim 1, further comprising at least one heat transfer device in thermal communication with the plastic body.

16. A method of manufacturing a three-dimensional cold plate for an electronic device having heat generating components, comprising the steps of:
Providing a metallic substrate with a top side and a bottom side;
pretreating and cleaning the metallic substrate;
etching the metallic substrate;
overmolding a three-dimensional molded contoured plastic body onto the bottom side of the metallic substrate to provide a bottom contoured side of the plastic body that substantially complementarily mates with a profile of heat generating components in an electronic device.

17. The method of claim 16 further comprising the step of:
overmolding a mechanically compliant and thermally conductive plastic material over the metallic substrate and plastic body without first sealing the metallic substrate and prior to substantial corrosion of the metallic substrate.

18. The method of claim 16, wherein the step of overmolding a mechanically complaint plastic material over the metallic substrate is carried out without first sealing the metallic substrate and prior to substantial corrosion of the metallic substrate.

19. The method of claim 16, further comprising the step of:
anodizing the metallic substrate.
